(19) United States
(12) Patent Application Publication
(10) Pub. No.: US 2025/0014938 A1
(43) Pub. Date: Jan. 9, 2025

(54) EDGE RINGS FOR IMPROVED EDGED UNIFORMITY IN SEMICONDUCTOR PROCESSING OPERATIONS

(71) Applicant: Lam Research Corporation, Fremont, CA (US)

(72) Inventors: Anand Chandrashekar, Fremont, CA (US); Leonard Wai Fung Kho, San Francisco, CA (US); Son Vo Nam Tran, Tracy, CA (US); Jared Ahmad Lee, San Jose, CA (US); Raul Vyas, Fremont, CA (US); Gang L. Liu, Fremont, CA (US); Jasmine Lin, San Jose, CA (US)

(21) Appl. No.: 18/712,211

(22) PCT Filed: Nov. 21, 2022
(86) PCT No.: PCT/US2022/080276

§ 371 Date: May 21, 2024

Related U.S. Application Data
(60) Provisional application No. 63/264,437, filed on Nov. 22, 2021.

(51) Int. Cl. H01L 21/687

(52) U.S. Cl. CPC H01L 21/68721

(57) ABSTRACT

Improved edge rings with flow conductance features are disclosed. The flow conductance features of the edge ring are features added to the edge ring that adjust the flow conductance of gas flowing in the local area of the edge ring. The flow conductance features can adjust the flow conductance to compensate for features on a semiconductor wafer, the edge ring, and in the chamber that may affect the flow of gas in the local areas. The flow conductance may be increased, reduced, or tuned depending on the desired effect.

### RELATED APPLICATION(S)

An Application Data Sheet is filed concurrently with this specification as part of the present application. Each application that the present application claims benefit of or priority to as identified in the concurrently filed Application Data Sheet is incorporated by reference herein in its entirety and for all purposes.

### BACKGROUND

It is often desirable to protect the edge of a semiconductor wafer during processing operations to prevent undesirable deposition or etching on the edges and/or the underside of the semiconductor wafer. One technology that is used to provide such edge protection is what is commonly referred to in the industry as an “exclusion ring” or “edge ring”. A typical edge ring features a ring structure that has an opening in the middle that is sized slightly smaller than the diameter of the semiconductor wafers with which it is to be used, such that when the edge ring is placed over, and centered on, the semiconductor wafer, the inner edge of the edge ring overlaps the exterior edge of the semiconductor wafer by some small amount.

### SUMMARY

In some implementations, an edge ring for use with a wafer having a diameter D and a thickness T including an outer portion having an outer bottom surface and an inner portion having a top surface, an inner bottom surface, and an inner edge may be provided. The outer bottom surface may define a first reference plane that is coplanar with at least a portion thereof. The inner bottom surface may define a second reference plane that is parallel to the first reference plane and coincident with at least a portion of the inner bottom surface. The inner bottom surface may be between the first reference plane and the top surface. The inner bottom surface may be at least a distance T away from the first reference plane. The inner edge may have a nominal inner diameter less than D. The edge ring may include one of the following: (a) a raised section within the inner portion with a raised section bottom surface between the first reference plane and the second reference plane, (b) an overhang section with material within a circular region centered within the edge ring and having a diameter equal to the nominal inner diameter, or (c) both (a) and (b).

In some implementations of the edge ring, the inner portion may have one or more recessed sections, each of the one or more recessed sections having a recessed bottom surface between the second reference plane and the top surface.

In some implementations of the edge ring, the inner portion has three recessed sections.

In some implementations of the edge ring, each recessed section of the one or more recessed sections may start at the inner edge of the inner portion and may extend towards an outer edge of the inner portion.

In some implementations of the edge ring, each recessed bottom surface of the one or more recessed sections may be at least 10 um away from the second reference plane.

In some implementations of the edge ring, each recessed section of the one or more recessed sections may have an arcuate outer edge.

In some implementations of the edge ring, each recessed section of the one or more recessed sections may have a straight outer edge.

In some implementations of the edge ring, the inner portion may have one or more angular sectors in which the inner edge is between the circular region and an outer edge of the inner portion.

In some implementations of the edge ring, the inner portion may have three angular sectors.

In some implementations of the edge ring, the inner edge at each of the one or more angular sectors may be between the circular region and a reference circle concentric with the circular region and a diameter D.

In some implementations of the edge ring, the inner edge at each of the one or more angular sectors may be an arcuate shape.

In some implementations of the edge ring, the inner edge at each of the one or more angular sectors may be straight.

In some implementations of the edge ring, the raised section bottom surface may be at least 300 um above the first reference plane.

In some implementations of the edge ring, the overhang section may have an overhang inner edge that is a chord of the circular region.

In some implementations of the edge ring, the overhang section may be sector-shaped.

In some implementations of the edge ring, the overhang section may be U-shaped.

In some implementations of the edge ring, the overhang section may have an overhang section bottom surface between the first reference plane and the second reference plane.

In some implementations of the edge ring, the inner edge may have a nominal inner diameter within 95% and 99.9% of D.

In some implementations of the edge ring, the edge ring may be made of a ceramic material.

In some implementations of the edge ring, the edge ring may further include a plurality of fingers, where each finger has a base, a radially inward-extending portion supported by the base, and a roller configured to rotate relative to the inward-extending portion, and the base of each finger is connected with the outer bottom surface.

In some implementations of the edge ring, D may be approximately 300 mm.

In some implementations of the edge ring, T may be approximately 775 um.

### BRIEF DESCRIPTION OF DRAWINGS

FIG. 1 shows a plan view of an example edge ring.

FIGS. 2-1 and 2-2 show a perspective view of an example edge ring with example fingers in different positions above an example pedestal.

FIG. 2-3 shows a detail view of an finger in the circled area of FIG. 2-1.

FIG. 3 is a cross-sectional view of an example edge ring over a semiconductor wafer on an example pedestal.

FIG. 4 shows the flow conductance of an example edge ring over an example semiconductor wafer.

FIGS. 5-1 and 5-2 are plan views of example edge rings with example overhang sections.

FIG. 6-1 is a cross sectional view of an example edge ring with an example overhang section.

FIGS. 6-2 and 6-3 are cross sectional views of example edge rings with example overhang sections and example raised sections.

FIGS. 6-4 and 6-5 are cross sectional views of example edge rings with example raised sections.

FIG. 7 is a plan view of an example edge ring with examples of feature section locations.

FIGS. 8-1, 8-2, and 8-3 are cross sectional views of example edge rings with example recessed sections.

FIG. 9 is a plan view of an example edge ring with examples of cut-out sections.

FIG. 10-1 is a cross sectional view of an example edge ring with an example cut-out section.

FIG. 10-2 is a cross sectional view of an example edge ring with an example cut-out section and example recessed section.

FIG. 11 show example recessed sections and example raised sections.

FIG. 12 depicts an example wafer processing chamber.

### DETAILED DESCRIPTION

In the following description, numerous specific details are set forth to provide a thorough understanding of the presented embodiments. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments.

In some semiconductor processing operations, an edge ring may be used to help control gas flow near the outer edge of a semiconductor wafer being processed. As noted earlier, such an edge ring may have an interior opening that is sized slightly smaller than the diameter of the wafer so as to overlap with the wafer by some small amount, e.g., millimeter or less when the edge ring is centered on, and placed over, the semiconductor wafer. The edge ring may, for example, be supported by the pedestal that supports the wafer such that the edge ring does not rest directly on the semiconductor wafer. An inert purge gas, e.g., argon, nitrogen, or other noble gas or gas that is non-reactive with respect to semiconductor processing gases may be introduced from orifices in the pedestal that supports the edge ring so as to flow into a gap in between the edge ring and the pedestal. The purge gas may then flow through this gap, past the edge of the semiconductor wafer, and then be directed radially inward towards the center of the semiconductor wafer via a gap between the underside of the edge ring and the top of the semiconductor wafer.

Some edge rings may also act as carrier rings that may support a semiconductor wafer during wafer placement and/or transfer operations. In some such edge rings, a plurality, e.g., three, fingers may extend radially inward from locations along the outer periphery of the edge ring. The fingers are located on the underside of the edge ring and are spaced apart from the surface of the edge ring that rests on the pedestal that supports the edge ring during processing operations. The fingers extend inward to points that are located within a circular region that is the same diameter as the wafer that is to be supported thereby. Thus, when a wafer is centered below the edge ring with the tips of the fingers located beneath the wafer, raising the edge ring upward will cause the tips of the fingers to contact the underside of the wafer and support the wafer from below, thus allowing the wafer to be lifted through further upward movement of the edge ring. The pedestal may, in turn, have recesses or receptacles in the upper surface that are sized to allow the fingers (and any associated supporting structures) to be lowered thereinto when the edge ring and semiconductor wafer are placed on the pedestal. The recesses or receptacles allow the fingers and supporting structures thereof to be lowered below the surface of the pedestal that supports the semiconductor wafer, thereby allowing the edge ring to descend to, and rest on or near, the surface of the pedestal that normally supports the semiconductor wafer.

The present inventors determined that in certain semiconductor processes, features such as the recesses or receptacles for receiving fingers that may be part of an edge ring (or other similar pockets or void spaces that are in fluidic communication with the underside of a wafer or edge ring when the wafer and edge ring are placed on the pedestal) can sometimes trap small amounts of process gases from one phase of a semiconductor processing operation that may then be undesirably released during a subsequent phase of the semiconductor processing operation. Such retained and later-released process gas may, in some cases, locally inhibit or interfere with (or potentially undesirably enhance, depending on the particular process in question) deposition or etching processes that are performed in the subsequent phase of the semiconductor processing operation, thereby causing an increased amount of non-uniformity near the edge of the wafer that overlies the recess or receptacles.

The present inventors also realized that features that may be located on the wafers themselves may also cause localized edge non-uniformities. For example, semiconductor wafers commonly have a notch or a flat edge along their perimeters that serves as a frame of reference that allows the rotational orientations of the semiconductor wafers to be reliably determined by different tools. Such an indexing feature allows for a determination to be made as to the rotational orientation of the semiconductor wafer with respect to a particular frame of reference/coordinate system. Once this information is obtained, the semiconductor wafer may then be rotated by a calculated amount in order to align the semiconductor wafer with a desired frame of reference/coordinate system. However, the notch, which often extends inward by a millimeter or two from the edge of the semiconductor wafer, may, in effect, interact with the edge ring so as to provide a small, localized region in which the flow conductance between the edge ring and the semiconductor wafer is higher than the flow conductance therebetween in most or all other locations around the edge ring. This, in turn, was found by the inventors to result in a locally elevated radially inward flow rate of the purge gas from the region between the edge ring and the pedestal. Thus, the flow rate of purge gas across the edge of the semiconductor wafer and towards the wafer center may be elevated at the location(s) along the semiconductor wafer's edge that overlay the notch(es) that may be present on the wafer. Some wafers have flats instead of notches, but a similar effect may be observed with such wafers as well (although potentially spread out along a larger portion of the outer circumference of the wafer).

The present inventors, having identified such issues as contributing to potential wafer non-uniformity, determined that such non-uniformities could be mitigated or even eliminated by modifying the structure of the edge ring such that the underside of the edge ring that overlaps with the wafer when in use has areas or regions that are raised and/or recessed with respect to the surface that forms the nominal underside of the edge ring that radially overlaps with a wafer when the wafer is present. Such areas or regions allow for local adjustment of the flow conductance in the gap between the underside of the edge ring and the top of the wafer to as to increase or decrease the amount of purge gas that flows radially inward at that location. The present inventors also determined that such non-uniformities could alternatively or additionally be mitigated or even eliminated by modifying the circular inner edge of the edge ring so as to have regions (which are positioned so as to align with features, e.g., wafer notches and/or recesses or receptacles in the pedestal) in which the inner edge moved radially inward or outward with respect to the circle that the inner edge of the edge ring lies along. Further details of such implementations are discussed in more detail below with respect to the Figures.

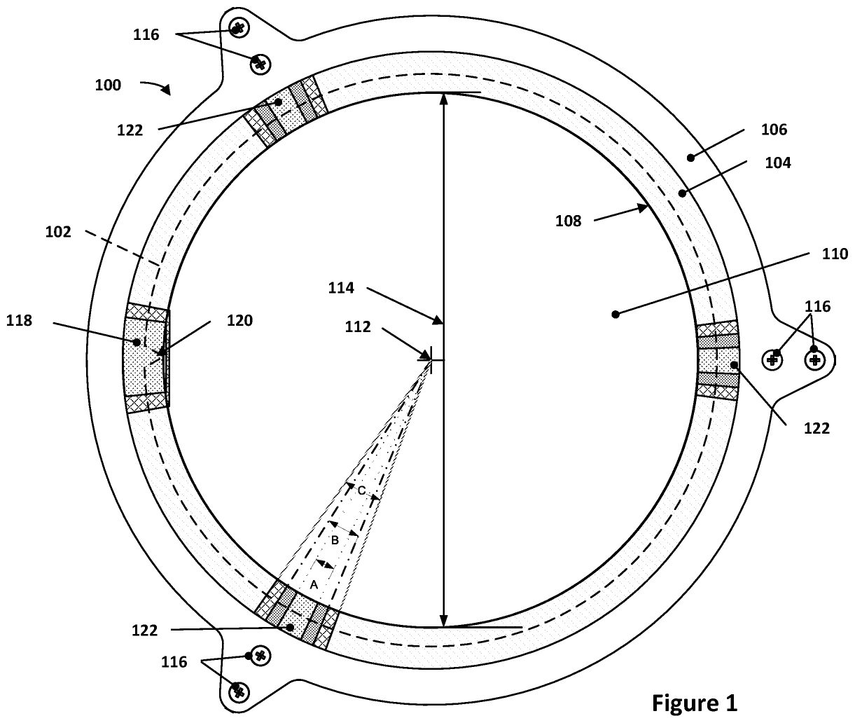

FIG. 1 depicts a plan view of an example edge ring 100 according to the present disclosure. The edge ring 100 has an outer portion 106 and an inner portion 104. The inner portion 104 has an inner edge 108. The inner edge 108 may define a substantially circular opening 110 centered on a ring center axis 112. The circular opening 110 has a diameter 114. The diameter 114 is slightly less than the diameter of a semiconductor wafer 102. In the example shown, the outline of an example semiconductor wafer 102 is shown. For example, a semiconductor wafer 102 may have a diameter of about 300 mm. In this example, the diameter 114 of the circular opening 110 is less than the 300 mm. The diameter 114 may be between 297-299.5 mm when used for processing 300 mm semiconductor wafer (FIG. 1, it will be understood, is not drawn to scale).

The edge ring 100 may have flow conductance features. The flow conductance features may be used to tune the flow conductance of the gap between the semiconductor wafer 102 and the overlapping portion of the inner portion 104 of the edge ring 100. The flow conductance features may be placed in specific locations to modify the flow conductance in corresponding areas around the semiconductor wafer 102. In the example shown in FIG. 1, the edge ring 100 has four locations where the flow conductance features are placed. The first three locations are each at a corresponding section 122 and the fourth location is at a notch section 118. Each section 122 may have a first type of flow conductance feature while the notch section 118 may have a second type of flow conductance feature, thereby allowing the radial flow conductance of the edge ring to be tuned to accommodate different purge gas flow rate needs at different locations. The notch section 118 may be located so as to align with a notch 120 of the semiconductor wafer 102 that the edge ring 100 is to be used with. The sections 122 may similarly generally be above recesses or receptacles in a pedestal (not shown) that are designed to receive fingers or similar structures attached to the edge ring 100. The fingers (not shown, but see FIGS. 2-1 and 2-3) and similar structures may be attached to the edge ring 100 by attachment screws 116.

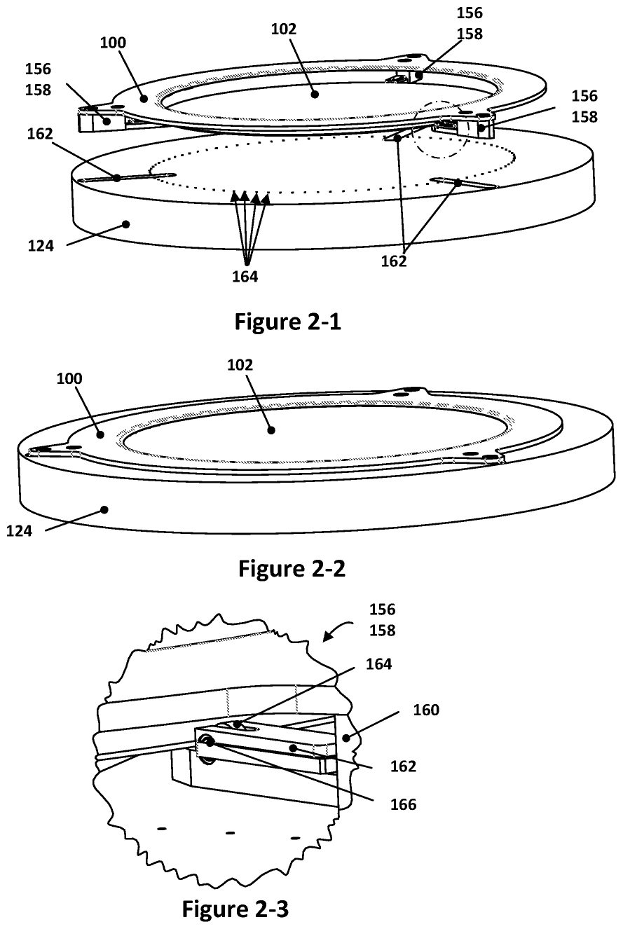

FIG. 2-1 shows a perspective view of the edge ring 100 holding the semiconductor wafer 102 in a raised position above a pedestal 124. The semiconductor wafer 102 is held by edge ring features 156 attached to the edge ring 100 by attachment screws. In this embodiment, the edge ring features 156 are fingers 158 having a roller 164. In the embodiment, there are three edge ring features 156. In some embodiments, there may be a single edge ring feature 156. In some embodiments, there may be two or more edge ring features 156 attached to the edge ring 100. The pedestal 124 may have one or more receptacles 162. The pedestal 124 has receptacles 162 to match the number of edge ring features 156. In the example shown, the edge ring 100 has three edge ring features 156 and the pedestal 124 has three receptacles 162. As discussed above, a receptacle 162 can sometimes trap small amounts of process gases during a semiconductor processing operation. This trapped gas may be undesirably released during a subsequent phase of the semiconductor processing operation and be a source of wafer non-uniformity. The pedestal 124 may also have a plurality of ports 163. The ports 163 may be used to deliver gases such as a purge gas to the underside of the edge ring during wafer processing.

FIG. 2-2 shows a perspective of the edge ring 100 in a lowered position over the pedestal 124. When the edge ring 100 is lowered from a raised position, as shown in FIG. 2-1, to the lowered position, the edge ring features 156 are lowered into their corresponding receptacle 162 on the pedestal 124. By having receptacles 162 for each edge ring feature 156, the edge ring 100 can lower the semiconductor wafer 102 onto the pedestal 124 and then continue to descend so as to ultimately rest on the pedestal as well while remaining slightly above the semiconductor wafer 102.

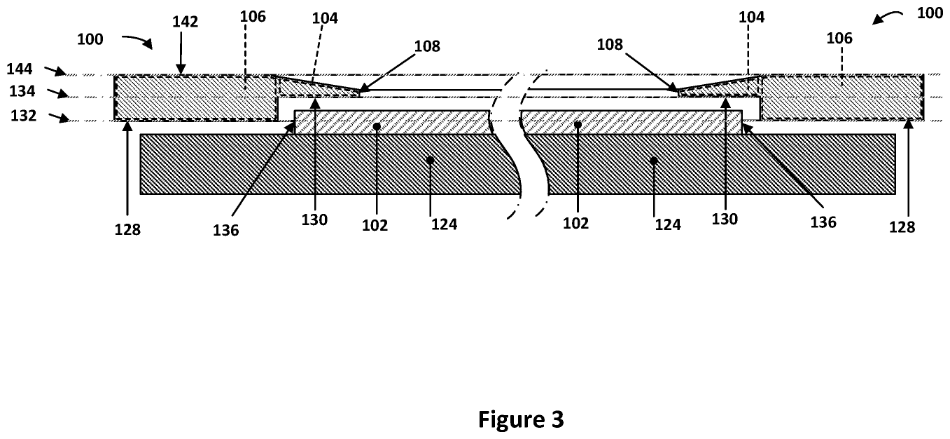

FIG. 2-3 shows a closer view of an example edge ring feature 156, a finger 158 having a roller 164. The finger 158 has a base 160. The base 160 supports an elongate structure 162 which extends from the base radially inward. A roller 164 is supported by the elongate structure 162 such that the roller is able to rotate relative to the elongate structure. In the example shown, the roller 164 is attached to the elongate structure 162 by a pin 166. The finger 158 is configured to fit into the receptacle 162 when the edge ring 100 is lowered towards the pedestal 124.

FIG. 3 shows a cross-sectional view of the edge ring 100. The cross-sectional view shows the edge ring overlapping an outer edge 136 of a semiconductor wafer 102. The semiconductor wafer 102 is placed on a pedestal 124. The edge ring 100 has the inner portion 104, the outer portion 106, and a top surface 142. The inner portion 104 has an inner edge 108. Generally, the inner edge 108 of the edge ring 100 is interior to the semiconductor wafer outer edge 136, i.e., the inner edge 108 of the edge ring 100 lies within a circle defined by the semiconductor wafer outer edge 136. There may be exceptions to this; for example, at a wafer notch (not shown), the outer edge of the semiconductor wafer may be interior to the inner edge 108 of the edge ring 100. As noted earlier, the diameter of the circular opening defined by the inner edge 108 has a nominal diameter less than the diameter of the semiconductor wafer 102 being processed. The inner portion 104 has an inner bottom surface 130 and the outer portion 106 has an outer bottom surface 128. The inner bottom surface 130 is at a higher elevation than the outer bottom surface 128. In some embodiments, the difference in elevation between the inner bottom surface 130 and the outer bottom surface 128 is the thickness of the semiconductor wafer 102. In some embodiments, the elevation of the inner bottom surface 130 may be a distance greater than the thickness of the semiconductor wafer 102 higher than the elevation of the outer bottom surface 128. In still some other embodiments, the difference in elevation between the inner bottom surface 130 and the outer bottom surface 128 may be less than the thickness of the semiconductor wafer 102. The wafer thickness, for example, may be approximately 750 um for a 300 mm diameter wafer.

Also shown in FIG. 3 is a first reference plane 132, a second reference plane 134, and top reference plane 144. The first reference plane 132 is coplanar with at least a majority of the outer bottom surface 128. The second reference plane 134 is parallel to the first reference plane 132 and is coincident with at least a majority of the inner bottom surface 130. The top reference plane 144 is coincident with the highest portion of the top surface 142 and parallel to the first reference plane 132.

FIGS. 5-1, 5-2, and 6-1 through 6-6 show examples of flow conductance features on an edge ring 500 over a notch 520 in a wafer 502. When an edge ring is used during semiconductor wafer processing, a notch area of the semiconductor wafer is minimally covered by the edge ring, i.e., an outer edge of the wafer at the notch is radially closer to an inner edge of the edge ring than the outer edge of the wafer in other portions wafer. Thus, during purge operations, the area around the notch is generally less obstructed and has a higher flow conductance than other locations around the inner perimeter of the edge ring. The high flow conductance may allow more purge gas to flow radially inward in the region around the notch compared to in other areas around the circumference of a semiconductor wafer.

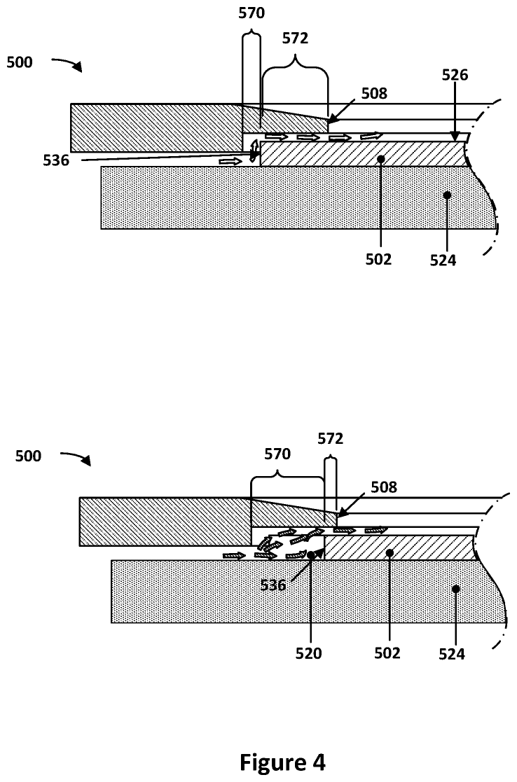

FIG. 4 shows flow conductance in the area around the notch of a semiconductor wafer compared to the flow conductance in other areas around the circumference of a semiconductor wafer. Shown in each figure is a cross-sectional view an edge ring 500 over a semiconductor wafer 502 on a pedestal 524. The top figure shows a cross-sectional view of the semiconductor wafer 502 under the edge ring 500 at a non-notch location along the wafer circumference while the bottom shows a cross-sectional view of the semiconductor wafer 502 under the edge ring 500 at a notch 520. Each view shows a higher-conductance region 570 and a lower-conductance region 572. Around the circumference, there is a larger radial distance between an inner edge 508 of the edge ring 500 and an outer edge 536 of the semiconductor wafer 502 and thus the smaller higher-conductance region 570 is smaller compared to the higher-conductance region 570 at the notch 520, where there is a smaller radial distance between the inner edge 508 of the edge ring 500 and the outer edge 536 of the semiconductor wafer 502. Since the higher-conductance region 570 is larger at the notch 520, there is generally a higher flow conductance in this area which allows more purge gas to flow radially inward compared to the other areas around the circumference of the semiconductor wafer. Flow conductance features in the edge ring may be used to reduce the flow conductance in the area around the notch of the semiconductor wafer. By using flow conductance features to reduce the flow conductance, the flow conductance around the wafer notch may be tuned so that the amount of gas remaining in the notch area after a purge is consistent with the amount of gas remaining in other areas around the circumference of the semiconductor wafer.

One example flow conductance feature that may be used to reduce the flow conductance in the vicinity of where a wafer notch will be is an overhang section. An overhang section, as the term is used herein, refers to a portion of the edge ring that extends radially inward from a circle that is generally concentric and co-radial with the inner edge of the edge ring. The overhang section may thus cause the inner edge in the notch section of an edge ring to be closer to the wafer center axis than the inner edge generally is around the most or all of the remainder of the inner edge, thereby extending the length of the shortest flow path that purge gas that flows from the notch feature of the wafer can follow before it reaches the inner edge of the edge ring. By extending the length of this flow path, the flow conductance of the flow path may be decreased, thereby offsetting the increased flow conductance that occurs in the notch area of the wafer.

FIGS. 5-1 and 5-2 show plan views of two examples of an edge ring 500 with flow conductance features. The flow conductance feature in each view is an overhang section 538. The edge ring 500 in FIG. 5-1 and FIG. 5-2 has an inner portion 504 and an outer portion 506. Also shown is the outline of a semiconductor wafer 502 with a notch 520. The overhang feature 538 in each figure causes the inner edge 508 at the notch section 518 of the edge ring 500 to be closer to the center of the wafer 502 in that region as compared with the nominal distance of the inner edge to the center of the semiconductor wafer 502. This acts to extend the radial flow path followed by the purge gas as it flows radially inward from the notch area of the wafer to the inner edge of the edge ring, thereby decreasing the flow conductance in that area so as to offset the increased flow conductance that results in the notch area of the wafer and helping to equalize the purge gas flow rate in the notch area with the nominal purge gas flow rate around the circumference of the edge ring.

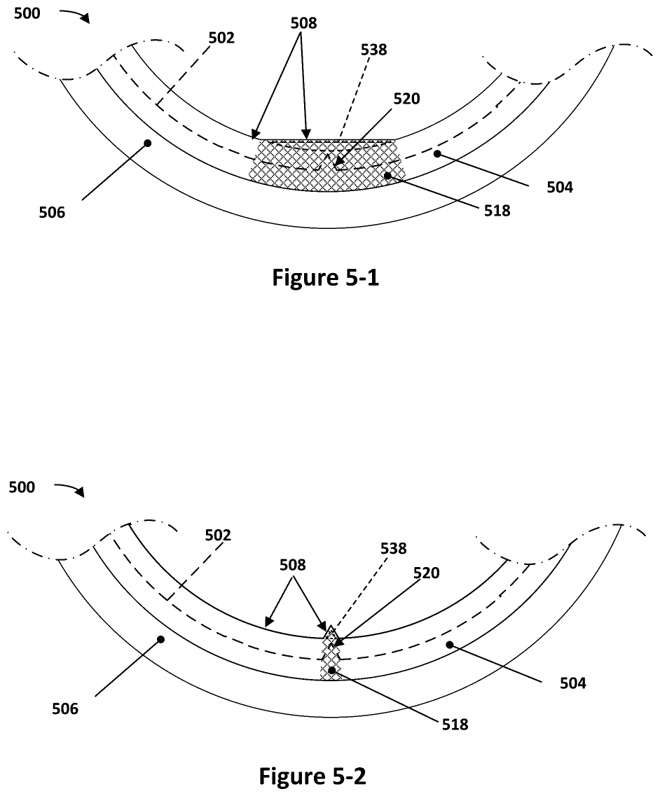

FIG. 5-1 shows a first example of an overhang section 538 of an edge ring 500. The overhang feature 538 in FIG. 5-1 is a portion of the edge ring that lies between a reference circle that is generally co-radial and concentric with the inner edge of the edge ring and a chord of that reference circle. The overhang feature 538 in FIG. 5-1 may thus be described as being chord-shaped. Such an overhang feature is perhaps larger than is needed but may be less susceptible to damage, less likely to be a source of nonuniformity itself, and more tolerant of angular misalignment of the notch feature in the wafer with respect to the edge ring. In the embodiment shown, the chord is just radially inward of the notch 520 of the semiconductor wafer 502. The inner edge 508 of the edge ring 500 at the notch section 518 is a straight line that is perpendicular to a radius of the edge ring that passes through the notch 520 and that is also interior of the entire notch 520 of the semiconductor wafer. However, it will be appreciated that similar overhang features may be used that do not feature straight lines, e.g., the straight line may be replaced by a constant- or variable-radius curve that slowly transitions between the arcuate edges of the edge ring on either side of the overhang feature to the portion of the inner edge of the overhang feature. Such overhang features may, in some implementations, be quite subtle—for example, a chord-shaped overhang feature with a chord width (measured from the interior edge of the overhang feature to the circle nominally defined by the interior edge of the edge ring) of less than 1 mm, e.g., 0.8 mm, 0.75 mm, 0.7 mm, 0.65 mm, etc., may be sufficient to provide sufficient flow conductance tuning to offset any increased flow conductance resulting from a wafer notch in some cases.

FIG. 5-2 shows a second example of an overhang section 538 of an edge ring 500. The overhang section 538 of FIG. 5-2 follows the shape of the wafer notch 520 and is generally a sector or triangular shape. Similar to the example in FIG. 5-1, the inner edge 508 of the edge ring 500 is radially inward of the reference circle that is generally co-radial and concentric with the inner edge of the edge ring. However, compared to the chord in FIG. 5-1, the sector shape generally follows the shape of the notch 520 of the semiconductor wafer 502, although offset outwards from the notch 520 such that there is a zone of the edge ring that extends around the notch area that overlaps with the wafer by some minimum overlap amount, e.g., one millimeter or so. The sector shape overhang section 538 may have a more limited effect on flow conductance compared to the chord-shaped overhang section in FIG. 5-1, thus providing a more localized flow conductance tuning approach as compared to the chord-shaped overhang section. In some embodiments, the overhang section 538 may be U-shaped, with the curved bottom of the U pointing radially inward toward the center of the edge ring.

Another example flow conductance feature that may be used to compensate for the increased flow conductance that is present near the wafer notch is a raised section, which is a region on the bottom surface of the inner portion of the edge ring that is “raised” relative to the majority of the bottom surface of the inner portion of the edge ring. As a result, the gap between the bottom surface of the edge ring and the wafer where such a raised section is located will be smaller than the gap that is between the wafer and most of the rest of the bottom surface of the inner portion of the edge ring. The flow conductance between the raised section and the wafer is thus lower than the flow conductance between the wafer and most of the rest of the bottom surface of the inner portion. Such raised sections may be used in isolation or may be combined with overhang features. Examples of raised sections are discussed below with respect to several of the Figures.

FIGS. 6-1 through 6-5 are cross-sectional views of an edge ring 500 with flow conductance features located over a notch 520 of a semiconductor wafer 502. In the examples shown, the semiconductor wafer 502 is on a pedestal 524. In each view, a first reference plane 532 coplanar with a majority of an outer bottom surface 528, a second reference plane 534, and a top reference plane 544 are shown. As discussed above, the second reference plane 534 is coincident with a majority of an inner bottom surface and parallel to the first reference plane 532. The top reference plane 544 is coincident with the highest portion of a top surface 542 and parallel to the first reference plane 532.

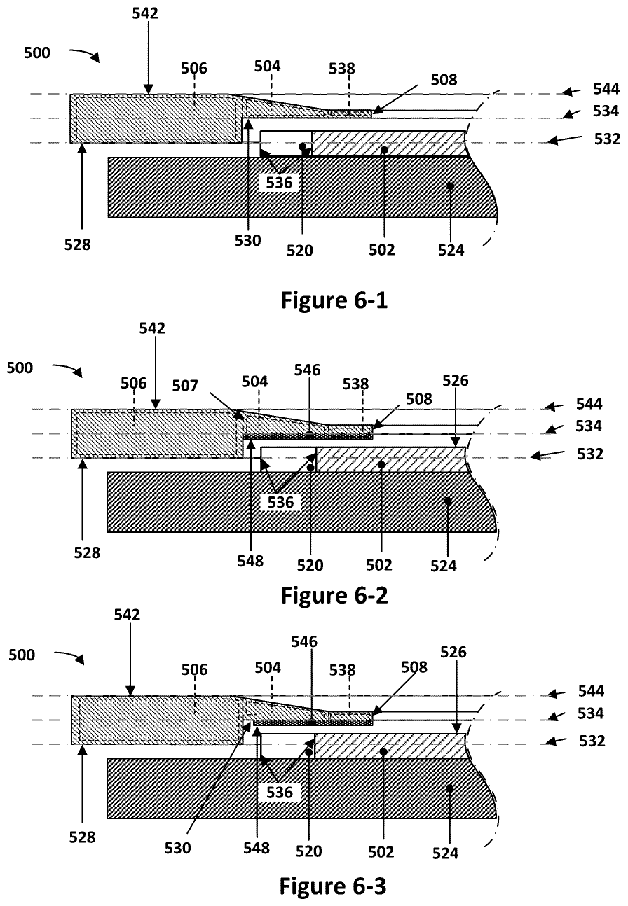

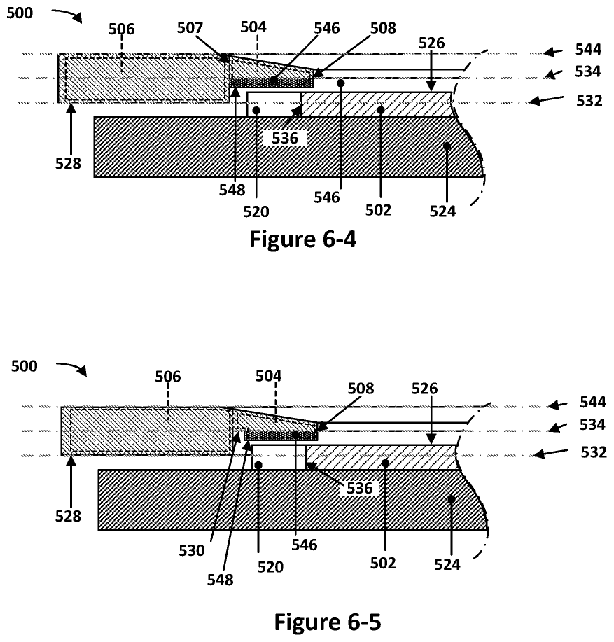

FIG. 6-1 shows the edge ring 500 having an overhang section 538. In the embodiment shown, the overhang section 538 locally extends the inner portion 504 of the edge ring 500 radially inward, moving the inner edge 508 inwards so that the inner edge in the overhang section is closer to the center of the edge ring than the inner edge is around most or all of the remainder of the edge ring 500. Depending on the flow conductance desired, the overhang section 538 may be extended or shortened.

FIG. 6-2 shows the edge ring 500 having an overhang section 538 and a raised section 546. The raised section 546 in FIG. 6-2 is indicated by the darker shaded region relative to the rest of the edge ring 500. The raised section 546 has a raised section bottom surface 548. The bottom surface 548 is between the first reference plane 532 and the second reference plane 534, thus positioning a portion of the bottom surface of the edge ring 500 closer to a top surface 526 of the semiconductor wafer 502. The raised section bottom surface 548 may be located anywhere between a top surface 526 of the semiconductor wafer 502 and the second reference plane 534. By having a raised section 546 the gap between the edge ring 500 and the semiconductor wafer 502 reduces, thus reducing the flow conductance in the area. The closer the raised section bottom surface 548 is to the wafer 502, the smaller the gap between the raised section bottom surface 548 and the semiconductor wafer 502. The smaller the gap between the raised section bottom surface 548 and the semiconductor wafer 502, the lower the flow conductance is in that region. In the embodiment shown, the raised section 546 extends from the overhang section 538 through the inner portion 504 to a boundary 507 between the inner portion 504 and the outer portion 506. The boundary 507 may also be referred to as the outer edge of the inner portion 504 or the inner edge of the outer portion 506.

FIG. 6-3 shows another embodiment of an edge ring 500 having both an overhang section 538 and a raised section 546. In this embodiment, the raised section 546 extends from the overhang section 538 into the inner portion 504. Unlike in the previous embodiment, the raised section 538 ends part of the way into the inner portion 504. In some embodiments, the raised section 538 may only be a segment of the inner portion 504 between the inner edge 508 and the boundary 507. In some embodiments, the raised section may not extend to the inner edge 508 of the inner portion 504. In these embodiments, the raised section starts radially outward of the inner edge 508.

FIG. 6-4 shows yet another example of an edge ring 500 with a flow conductance feature of a raised section 546 for use over the notch 520 of the semiconductor wafer 502. The raised section 546 extends outward from the nominal bottom surface of the edge ring 500 so that a bottom surface 548 of the raised section 546 is between atop surface 536 of the semiconductor wafer 502 and the second reference plane 534. The raised section 546 extends from the inner edge 508 through the inner portion 504 until a boundary 507 between the inner portion 504 and the outer portion 506. In the example shown, the edge ring 500 does not have an overhang section as shown in the previous examples. Thus, the flow conductance is modified only by the decreased gap between the bottom surface 548 of the raised section 546 and a top surface 526 of the semiconductor wafer 502.

FIG. 6-5 shows another example of an edge ring 500 with a flow conductance feature of a raised section 546 for over the notch 520 of the semiconductor wafer 502. Similar to the example in FIG. 6-4, in this example the raised section extends outward so that a bottom surface 548 of the raised section 546 is between a top surface 526 of the semiconductor wafer 502 and the second reference plane 534. In this example, the raised section 546 extends from the inner edge 508 through the inner portion 504 towards the outer portion 506. The raised section 546 ends part way into the inner portion 504 before extending to a boundary 507 between the inner portion and the outer portion 506. In some embodiments, the raised section 546 may be a segment of the inner portion 504 between the inner edge 508 and the boundary 507. The segment of the raised section 546 may be designed to create a desired flow conductance in the area above the notch 520 of the wafer 502.

While the above-discussed flow conductance features may be used to decrease flow conductance in a localized area of an edge ring, e.g., to offset increased flow conductance that may be present due to features such as wafer notches, a second type of flow conductance features may be used to locally increase flow conductance so as to increase purge gas flow rate in particular areas around the circumference of the edge ring. Generally speaking, such flow conductance features may be used where features on an edge ring, e.g., a finger, that may require the presence of recesses or receptacles in the pedestal are located. Such recesses or receptacles may trap gases that may resist being purged through the standard purging gas flows that may be provided by an edge ring. The second type of flow conductance features may increase the flow conductance in these areas, allowing for locally increased purge gas flow that may act to more efficiently remove the trapped gas, thus preventing such trapped gas from leaking out slowly over a longer period of time and potentially interfering with subsequent processing operations. Examples of the second type of flow conductance features include a recessed section in the bottom surface of the inner portion of the edge ring, a cut-out section along the inner edge of the edge ring, or a combination thereof.

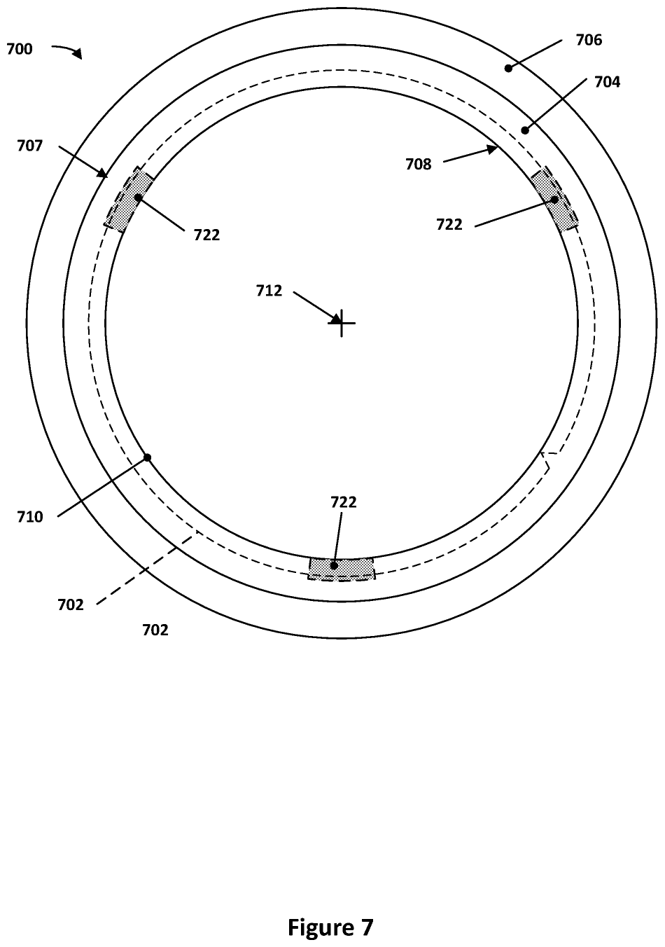

FIG. 7 depicts a plan view of an example edge ring 700 with three feature sections 722. In some embodiments there may be a single feature section. In some embodiments, there may be two or more feature sections. Such implementations may, for example, be used in situations in which there are other than three recesses or receptacles in the pedestal.

The edge ring 700 has an outer portion 706 and an inner portion 704. The inner portion 704 has an inner edge 708. The inner edge 708 may define a substantially circular opening 710 centered on a ring center axis 712. A semiconductor wafer 702 with an outer edge 736 is shown. The inner edge 708 of the inner portion 704 is interior to the outer edge 736 of the semiconductor wafer 702. As discussed with respect to FIG. 1, sections 722 have features below the edge ring 700 that may require the presence of recesses or receptacles in the pedestal to house such features when the edge ring is placed on top of the pedestal. Such recesses or receptacles may trap or contain processing gases that may then leak out slowly and potentially interfere with subsequent processing operations using other gases. It may thus be desirable to provide for localized areas of the edge ring with higher flow conductance to enhance the purge rate of such areas. If the purge rate is left at the “default” purge rate in such areas, the processing gas that leaks out of the recesses or receptacles may cause localized processing non-uniformities on the semiconductor wafer 702 around the sections 722 to increase. The flow conductance features discussed above may be located in these sections to improve purge gas flow rate in these areas, thereby allowing the trapped process gases to be more expediently removed.

As mentioned earlier, one type of flow conductance feature that may be used is a recessed section (not shown). Such flow conductance features are usually cut from a bottom surface of the inner portion 704. The sections 722 highlight the area of the edge ring 700 that may be modified to incorporate a flow conductance feature. In the embodiment shown, the sections 722, and thus the flow conductance features, i.e., recessed sections, have an arcuate outer edge. In this embodiment, the arcuate edge follows an arc of a circle concentric with the edge ring 700. In some embodiments, the recessed section may have a straight outer edge. In some embodiments, the recessed sections may extend from the inner edge 708 through the inner portion 704 to a boundary 707 between the inner portion 704 and the outer portion 706. The boundary 707 is where an inner portion outer edge meets an outer portion inner edge and may be referred to as either the inner portion outer edge or outer portion inner edge. In some embodiments, the recessed section may only cover a segment of the inner portion 704 that extends radially outward. In these embodiments, the recessed section may extend to one of or neither of the boundary 707 and inner edge 708 of the inner portion 704.

FIG. 8-1 through FIG. 8-3 show three cross sectional areas of edge rings 700 each with an example recessed section 750. Each figure shows an edge ring 700 with an outer portion 706, inner portion 704, and a top surface 742. The inner portion 704 meets the outer portion 706 at a boundary 707. The inner portion 704 has an inner bottom surface 730 and an inner edge 708. The outer portion 706 has an outer bottom surface 728. A first reference plane 732 is coplanar at with a majority of the outer bottom surface 728. A second reference plane 734 is coincident with a majority of the inner bottom surface 730 and is parallel to the first reference plane 732. A top reference plane 744 is coincident with a highest portion of the top surface 742 and is parallel to the first reference plane 732. The second reference plane 734 is between the first reference plane 732 and the top reference plane 744. Shown in each figure is a semiconductor wafer 702 on a pedestal 724. The semiconductor wafer 702 has an outer edge 736 and a top surface 726. In each figure, the wafer outer edge 736 is radially outwards of the inner edge 708 of the inner portion 704, i.e., the inner edge 708 of the inner portion 704 lies within a circle defined by the wafer outer edge 736.

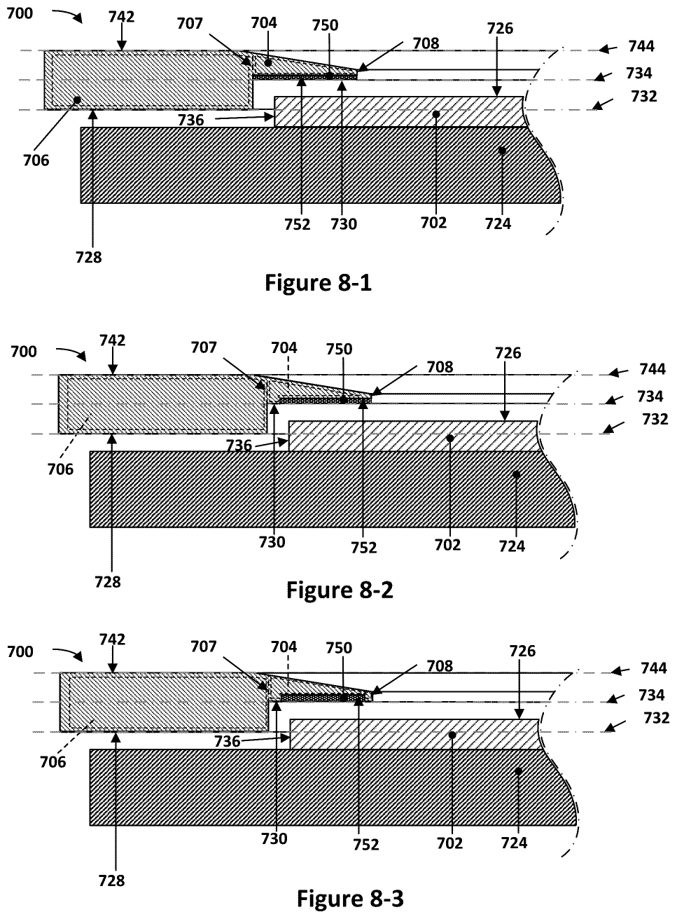

FIG. 8-1 shows a first example of a recessed section 750. The recessed section 750 is an area where material has been removed from the inner portion 704 of the edge ring 700, thereby creating a recessed section bottom surface 752. The recessed section bottom surface 752 may be anywhere between the second reference plane 734 and the top reference plane 744. In some implementations, the recessed section bottom surface 752 may be at least 10 um away from the second reference plane 734. In some implementations, the recessed section bottom surface 752 may be up to a distance of 200 um away from the second reference plane 734. The recessed section 750 raises the bottom surface in the local area of the edge ring 700, creating a larger gap between a portion of a bottom surface of the edge ring 700 and a wafer top surface 726. The enlarged gap may cause the flow conductance in that area to be increased and thus may encourage a higher purge gas flow rate that more effectively purges any process gas in the area around the recessed section 750. Generally, the closer the recessed section bottom surface 752 is to the top reference plane 744, the higher the flow conductance. As shown in FIG. 8-1, the recessed section may extend from the inner edge 708 to the boundary 707.

FIG. 8-2 shows a second example of a recessed section 750 on the edge ring 700. Similar to FIG. 8-1, a recessed section bottom surface 752 is raised so that it is between the second reference plane 734 and the top reference plane 744. In the example shown, the recessed section 750 extends from the outer edge 708 and towards the outer portion 706. However, unlike the example in FIG. 8-1, the recessed section ends before the boundary 707 between the inner portion 704 and the outer portion 706. In the embodiment shown, while the recessed section 750 ends before the boundary 707, the recessed section 750 still extends past the wafer outer edge 736. In some embodiments, the recessed section 750 may be shorter, such that the wafer outer edge 736 is radially outward to the entire recessed section 750, i.e., the wafer outer edge 736 is further away from the center of the edge ring 700 than an outer edge of the recessed section. Generally, the longer the radial distance over which the recessed section extends, the higher the flow conductance. Thus, the flow conductance created in this embodiment may be less than the flow conductance created in the embodiment shown in FIG. 8-1.

FIG. 8-3 shows a third example of a recessed section 750 on the edge ring 750. Similar to the prior examples, the recessed section 750 has a recessed section bottom surface 752. The recessed section bottom surface 752 raises the bottom surface of the edge ring 700 in the local area and is between the second reference plane 734 and the top reference plane 744. In the embodiment shown, the recessed section 750 is contained radially within the inner portion 704 of the edge ring 700 and does not extend to neither the boundary 707 nor the outer edge 708. In some embodiments, the recessed section 750 may extend radially all the way to the boundary 707 but not to the inner edge 708 of the inner portion 704. The recessed section 750 may span any radial segment of the inner portion 704 between the inner edge 708 and the boundary 707.

A recessed section is one example of flow conductance feature which may be used to increase the flow conductance in specific areas of an edge ring. Another example of a flow conductance feature is a cut-out section. A cut-out section is a section within an inner portion of the edge ring where material is removed. Generally speaking, cut-out sections have an inside edge that lies outside of a reference circle that is generally co-radial and concentric with the inner edge of the edge ring. In some embodiments, the inside edge at the cut-out section still remains interior to an outside edge of a semiconductor wafer. A cut-out section reduces the distance gas has to travel between the edge ring and semiconductor wafer, thereby increasing flow conductance in these areas compared to sections of the edge ring without flow conductance features.

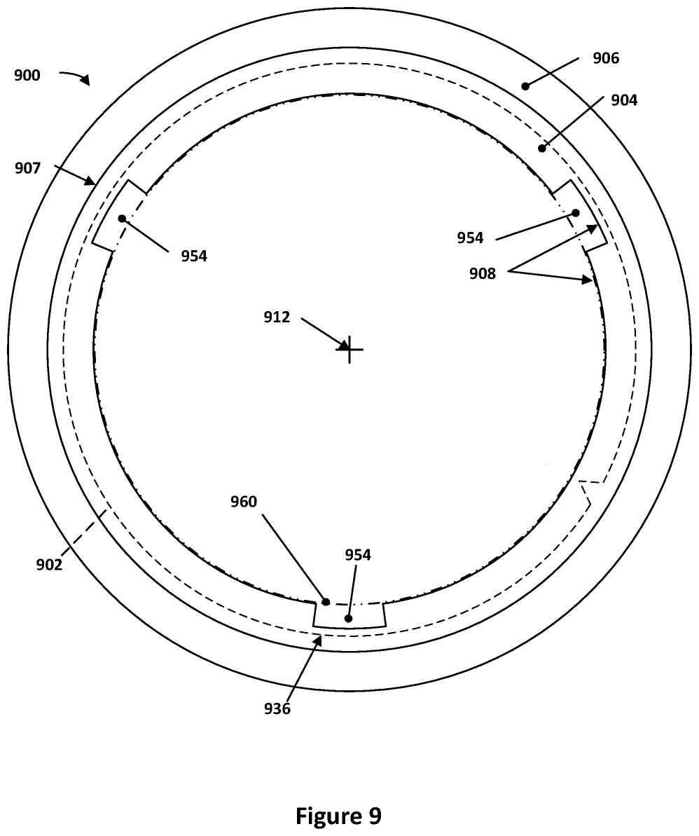

FIG. 9 depicts a plan view of another example edge ring 900 with three cut-out sections 954. In some embodiments, there may be a single cut-out section. In some embodiments, there may be two or more cut-out sections. Such implementations may, for example, be used in situations in which there are other than three recesses or receptacles in the pedestal.

Shown in the figure is a semiconductor wafer 902. The edge ring 900 has an outer portion 906 and an inner portion 904. The inner portion 904 has an inner edge 908. The semiconductor wafer 902 has a reference circle 960 that is generally co-radial and concentric with the inner edge 908 of the edge ring 900 that is centered on a ring center axis 912, i.e., the reference circle 960 is concentric with the inner edge 908 not part of each of the three cut-out sections 954. At each of the three cut-out sections 954, the inner edge 908 of the inner portion 904 is moved radially outward so that the inner edge is between the reference circle 960 and a boundary 907 between the inner portion 904 and the outer portion 906. As describe in figures above, the boundary 907 is where the inner portion outer edge outer portion inner edge meet. In the embodiment shown, the cut-out section 954 is an angular sector from the ring center axis 912. The inner edge 908 at the cut-out section 954 is an arcuate shape. In some embodiments the inner edge 908 at the cut-out section 954 may be a straight line. The arcuate shape may be less than 5 degrees. In some embodiments, the arcuate shape may be between 5 and 10 degrees. In still some other embodiments, the arcuate shape may be greater than 10 degrees. In some embodiments, the cut-out section may be a rectangular shape (not shown).

As shown in FIG. 9, the inner edge 908 at the cut-out section 954 is moved radially outwards toward the outer portion 906 relative to the non-cut-out section areas. In the embodiment shown, the inner edge 908 at each cut-out section 954 is approximately midway between the reference circle 960 and the boundary 907. In this embodiment, the inner edge 908 at the cut-out sections 954 remain radially interior to a wafer outer edge 936, i.e., the inner edge 908 at each cut-out section lies within a circle concentric and co-radial with the wafer outer edge. It should be noted that the examples shown are exaggerated in size to allow for clearer viewing; such cutouts and wafer overlap may be much smaller than shown, e.g., radial depths of the cutouts may be a millimeter or so. In some implementations, the radial depths of such cutouts may be less than a millimeter, e.g., less than 0.9 mm, less than 0.8 mm, less than 0.7 mm, less than 0.6 mm, less than 0.5 mm, less than 0.4 mm, less than 0.3 mm, etc. In some embodiments, the cut-out section 954 may have the inner edge 908 closer to the reference circle 960 such that the inner edge at the cut-out section is closer to the reference circle 960 than the wafer outer edge 936. In some other embodiments, the cut-out section 954 may have the inner edge 908 closer to the boundary 907 such that the inner edge is above or slightly radially interior to the wafer outer edge 936.

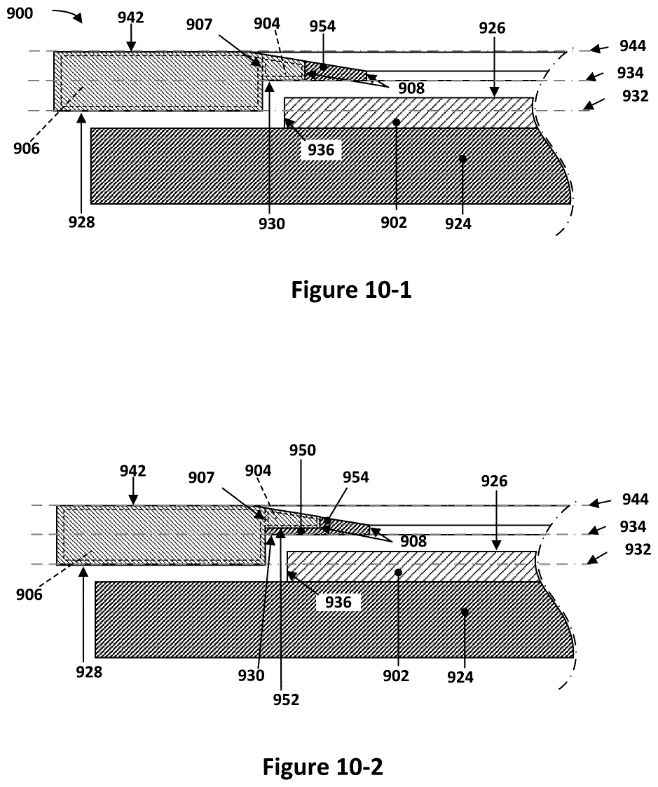

FIGS. 10-1 and 10-2 show cross-sectional views of example cut-out sections 954 on an edge ring 900. In FIG. 10-1, the edge ring 900 has a single flow conductance feature, a cut-out section. The example in FIG. 10-2 has two flow conductance features on an edge ring 900, a cut-out section 954 and a recessed section 950. In both figures, the edge ring 900 has an outer portion 906, an inner portion 904, and a top surface 942. The inner portion 904 meets the outer portion 906 at a boundary 907. The boundary 907 may be referred to as the outer edge of the inner portion 904 or inner edge of the outer portion 906. The inner portion 904 has an inner bottom surface 930 and an inner edge 908. The outer portion 906 has an outer bottom surface 928. A first reference plane 932 is coplanar with a majority of the outer bottom surface 928. A second reference plane 934 is coincident with a majority of the inner bottom surface 930 and is parallel to the first reference plane 932. A top reference plane 944 is coincident with a highest portion of the top surface 942 and is parallel to the first reference plane 932. Shown in each figure is a semiconductor wafer 902 on a pedestal 924. The semiconductor wafer 902 has an outer edge 936. In each figure, the outer edge 936 is radially outward of the inner edge 908 of the inner portion 904.

The cross-sectional view in FIG. 10-1 shows the cut-out section 954 of the edge ring 900. Behind the cut-out section 954 is the edge ring 900 without a flow conductance feature, i.e., the normal edge ring without any cut-out section, which is indicated by a darker shaded region. The cut-out section 954 has the inner edge 908 closer to the outer portion 906 of the edge ring 900 reducing the overhang of the edge ring 900 over the semiconductor wafer 902 in the local area. As described with reference to FIG. 9, the cut-out section 954 may extend radially inward such that the material removed is reduced, or may extend radially outward, such that the material removed is greater. For example, the cut-out section 954 may remove the inner portion 904 in the area, leaving the inner edge 908 above or slightly interior to the wafer outer edge.

In the embodiment shown, the inner bottom surface 930 is unchanged and remains at the same height as the rest of the edge ring 900. Thus, in this embodiment, the flow conductance in the area is changed by reducing the overhang of the edge ring 900 by the cut-out section 954 and not by changing the gap between the inner bottom surface 930 and a top surface 926 of the semiconductor wafer 902.

In the embodiment in FIG. 10-2, an edge ring 900 has both a cut-out section 954 and a recessed section 950. Unlike in the previous embodiment, both the amount of overhang of the edge ring 900 over the semiconductor wafer 902 and the gap between a bottom surface of the edge ring 900 and a top surface 926 of the semiconductor wafer 902 are modified to change the flow conductance in the area. The cut-out section 954 may be made so that the inner edge 908 of the inner portion 904 at the cut-out section 954 is approximately midway between the inner edge of an unmodified inner portion and the boundary 907. In the embodiment shown, the inner edge 908 of the cut-out section 954 is radially interior to the wafer outer edge 936. The cut-out section 954 can be made deeper, e.g., the inner edge at the cut-out section may be moved closer toward the outer portion 906, or shallower, e.g., the inner edge at the cut-out section may be moved away from the outer portion 906, depending on the desired flow conductance. In some embodiments, the cut-out section 954 may be made deeper towards the outer portion 906. In some embodiments, the cut-out section 954 may be made shallower so that the inner edge 908 is closer to a center (not shown) of the semiconductor wafer 902. The recessed section 950 raises a recessed section bottom surface 952 away from the wafer top surface 926. The recessed section bottom surface 952 is between the top reference plane 944 and the second reference plane 934. The recessed section 950 may be modified as described with reference to FIGS. 8-1 through 8-3.

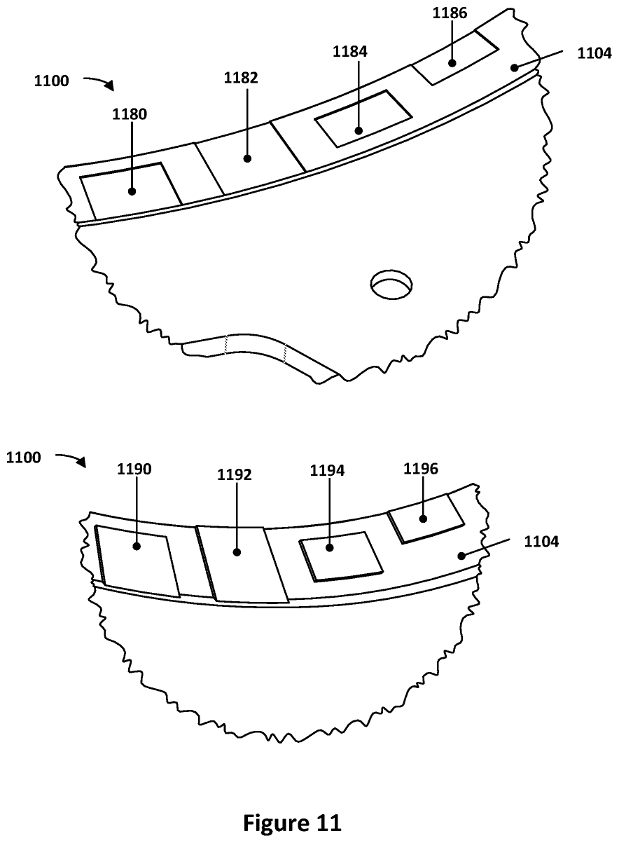

To assist with further understanding and to provide additional insight, various example recessed sections and raised sections are shown in FIG. 11. FIG. 11 provides four example recessed sections and four raised sections on an inner portion 1104 of an edge ring 1100; these flow conductance features are all placed side-by-side for comparison. A first recessed section 1180 is an example of the embodiment discussed with respect to FIG. 8-3. A second recessed section 1182 is a perspective view of an example of the recessed section 650 shown in FIG. 8-1. A third recessed section 1184 is a perspective view of an example recessed section 650 shown FIG. 8-3. A fourth recessed section 1186 is a perspective view of an example recessed section 750 shown in FIG. 8-2. A first raised section 1190 is an example of the embodiment discussed with respect to FIG. 6-5. A second raised section 1192 is a perspective view of an example of the raised section 546 shown in FIG. 6-4. A third raised section 1194 is another example of the embodiment discussed with respect to FIG. 6-5. A fourth raised section 1196 is a perspective view of an example raised section 646 shown in FIG. 6-5.

Returning to FIG. 1, each of the sections 122 may be located above a corresponding feature, such as the features 156 shown in FIG. 2. The sections 122 may extend through circumferential regions or sectors of arc that may vary depending on the particular flow conductance characteristics desired, e.g., as shown by the three different sizes of feature sections. In the example shown, the sections 122 annular sectors of the inner portion of the edge ring 100. In some embodiments, the sections 122 may be rectangles that extend to the inner edge 108.

Similarly, the notch section 118 is located above the notch 120 of the semiconductor wafer 102. The notch section 118 may extend through circumferential regions or sectors of arc that may vary depending on the particular flow conductance characteristics desired, e.g., as shown by the two different sizes of feature sections. In the example shown, the notch sections 122 annular sectors of the inner portion of the edge ring 100. In some embodiments, the sections 122 may be rectangles that extend to the inner edge 108.

The edge rings having features discussed herein may be made of materials such as ceramics, e.g., aluminum oxide, aluminum nitride, silicon oxide, silicon nitride, quartz, or other materials that are chemically resistant and other wise appropriate for use in semiconductor processing environments.

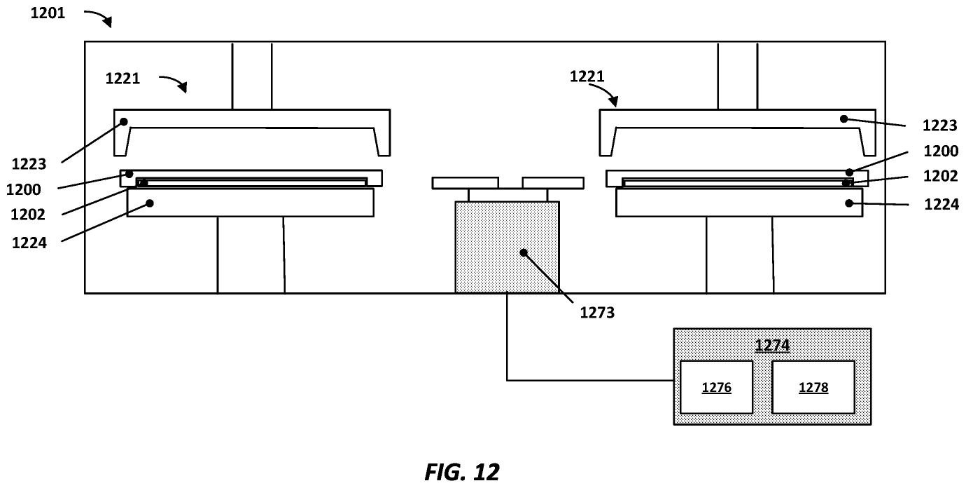

In some implementations, the edge rings discussed herein may be used in, or part of, a system that includes a controller. FIG. 12 depicts an example wafer processing chamber 1201. The chamber 1201 shown has multiple wafer processing stations 1221 each with a showerhead 1223 and a pedestal 1224. In each wafer processing station 1221 is a corresponding edge ring 1200 and a semiconductor wafer 1202. The wafer processing chamber 1201 has a wafer handler 1273, e.g., a rotational indexer, carousel, or wafer handling robot, that may be used to transport wafers between stations. Connected to the wafer processing chamber is an example controller 1274. The controller 1274 has one or more processors 1278 and a memory 1276, which may be integrated with electronics for controlling the operation of edge rings 1200 and/or wafer handlers to place and/or align wafers on edge rings. The controller 1274, depending on the processing requirements and/or the type of system, may be programmed to control any of the processes disclosed herein, such as processes for controlling the placement and alignment of wafers on edge rings, as well as other processes or parameters not discussed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a chamber and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example edge rings according to the present disclosure may be mounted in or part of semiconductor processing tools with a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. An edge ring for use with a wafer having a diameter D and a thickness T comprising:
an outer portion having an outer bottom surface; and
an inner portion having a top surface, an inner bottom surface, and an inner edge, wherein:
the outer bottom surface defines a first reference plane that is coplanar with at least a portion thereof;
the inner bottom surface defines a second reference plane that is parallel to the first reference plane and coincident with at least a portion of the inner bottom surface;
the inner bottom surface is between the first reference plane and the top surface;
the inner bottom surface is at least a distance T away from the first reference plane;
the inner edge has a nominal inner diameter less than D; and
the edge ring includes one of the following:
(a) a raised section within the inner portion with a raised section bottom surface between the first reference plane and the second reference plane;
(b) an overhang section with material within a circular region centered within the edge ring and having a diameter equal to the nominal inner diameter; or
(c) both (a) and (b).

2. The edge ring of claim 1, wherein the inner portion has one or more recessed sections, each of the one or more recessed sections has a recessed bottom surface between the second reference plane and the top surface.

3. The edge ring of claim 2, wherein the inner portion has three recessed sections.

4. The edge ring of claim 2, wherein each recessed section of the one or more recessed sections starts at the inner edge of the inner portion and extends towards an outer edge of the inner portion.

5. The edge ring of claim 2, wherein each recessed bottom surface of the one or more recessed sections is at least 10 um away from the second reference plane.

6. The edge ring of claim 2, wherein each recessed section of the one or more recessed sections has an arcuate outer edge.

7. The edge ring of claim 2, wherein each recessed section of the one or more recessed sections has a straight outer edge.

8. The edge ring of claim 1, wherein the inner portion has one or more angular sectors in which the inner edge is between the circular region and an outer edge of the inner portion.

9. The edge ring of claim 8, wherein the inner portion has three angular sectors.

10. The edge ring of claim 8, wherein the inner edge at each of the one or more angular sectors is between the circular region and a reference circle concentric with the circular region and a diameter D.

11. The edge ring of claim 8, wherein the inner edge at each of the one or more angular sectors is an arcuate shape.

12. The edge ring of claim 8, wherein the inner edge at each of the one or more angular sectors is straight.

13. The edge ring of claim 1, wherein the raised section bottom surface is at least 300 um above the first reference plane.

14. The edge ring of claim 1, wherein the overhang section has an overhang inner edge that is a chord of the circular region.

15. The edge ring of claim 1, wherein the overhang section is sector-shaped.

16. The edge ring of claim 1, wherein the overhang section is U-shaped.

17. The edge ring of claim 1, wherein the overhang section has an overhang section bottom surface between the first reference plane and the second reference plane.

18. The edge ring of claim 1, wherein the inner edge has a nominal inner diameter within 95% and 99.9% of D.

19. The edge ring of claim 1, wherein the edge ring is made of a ceramic material.

20. The edge ring of claim 1 further comprising a plurality of fingers, wherein:
each finger has a base, a radially inward-extending portion supported by the base, and a roller configured to rotate relative to the inward-extending portion, and
the base of each finger is connected with the outer bottom surface.

21. The edge ring of claim 1 wherein D is approximately 300 mm.

22. The edge ring of claim 1 wherein T is approximately 775 um.
